(19) United States
(12) Patent Application Publication
(10) Pub. No.: US 2012/0017832 A1
(43) Pub. Date: Jan. 26, 2012

(54) VAPOR DEPOSITION APPARATUS AND SUSCEPTOR

(76) Inventors: Wei-Cheng CHEN, Tainan City (TW); Zong-Lin Lee, Tainan City (TW); Kung-Ming Liang, Tainan City (TW); Yung-Hsin Shie, Tainan City (TW)

(21) Appl. No.: 13/010,598

(22) Filed: Jan. 20, 2011

(30) Foreign Application Priority Data
Jul. 21, 2010 (TW) 099124024

(51) Int. Cl. C23C 16/06; C23C 16/511; C23C 16/448

(52) U.S. Cl. 118/723 MW; 118/722; 118/730

(57) ABSTRACT

A vapor deposition apparatus includes a susceptor, a gas supply unit, a heating unit and a rotation unit. The susceptor has a first substrate-holding portion and a second substrate-holding portion. The first substrate-holding portion has a first depth, and the second substrate-holding portion has a second depth that is larger than the first depth. The gas supply unit supplies precursors to the susceptor. The heating unit is used to heat the susceptor. The rotation unit can rotate the susceptor so that the heating unit can uniformly heat the susceptor. Because the second depth is larger than the first depth, the substrate held in the second substrate-holding portion can not directly contact the susceptor with a higher temperature and thus its temperature is lower than the second substrate-holding portion, so as to maintain the uniformity of the properties of the manufactured chips.

### CROSS REFERENCE TO RELATED APPLICATIONS

This Non-provisional application claims priority under 35 U.S.C. §119(a) on Patent Application No(s). 099124024 filed in Republic of China on Jul. 21, 2010, the entire contents of which are hereby incorporated by reference.

### BACKGROUND OF THE INVENTION

1. Field of Invention

The invention relates to a semiconductor processing apparatus and, in particular, to a vapor deposition apparatus and a susceptor.

2. Related Art

The vapor deposition apparatus is a common semiconductor processing apparatus, which can utilize MOCVD (metalorganic chemical vapor deposition) method or MOVPE (metalorganic vapor phase epitaxy) method to form a thin film on a wafer for manufacturing various semiconductor devices, such as the light-emitting diode (LED), laser diode, solar cell, or the likes.

During the MOCVD process, a carrier gas passes through a container containing a metalorganic precursor and brings the saturated vapor of the precursor to the reactive chamber to mix with other reactive gases, and then the chemical reaction takes place on the heated wafer to induce the epitaxial growth of the thin film. The wafer mentioned above is disposed on a susceptor, which has a plurality of wafer-holding portions for holding wafers and is heated by a heating mechanism for chemical reactions. Besides, a rotation mechanism is provided and is connected to the susceptor, thereby rotating the susceptor, so that wafers on the susceptor can be heated uniformly.

As shown in FIG. 1, a conventional susceptor 10 has 31 wafer-holding portions 11 (No. 1 to No. 31), each of which accommodates a wafer (e.g. a two-inch wafer). FIG. 2 shows a cross-sectional view of the wafer-holding portion 11. Referring to FIG. 2, the wafer-holding portion 11 has a depression with a depth H for accommodating the wafer W. However, according to FIG. 1, when the susceptor 10 rotates, the wafer-holding portion 11 of No. 1 almost rotates about the same location, so that it receives more heat than other wafer-holding portions. Consequently, among the chips of the same production batch, the chip (such as a blue LED) of No. 1 has an abnormal short wavelength, resulting in decrease of the production yield.

Therefore, it is an important subject to provide a vapor deposition apparatus and a susceptor that can adjust the heat received by each wafer on respective wafer-holding portion so as to improve the production yield.

### SUMMARY OF THE INVENTION

In view of the foregoing subject, an objective of the invention is to provide a vapor deposition apparatus and a susceptor that can adjust the heat received by the substrates on the substrate-holding portions so as to improve the production yield.

To achieve the above objective, a vapor deposition apparatus according to the invention includes a susceptor, a gas supply unit, a heating unit and a rotation unit. The susceptor has a first substrate-holding portion and a second substrate-holding portion, the first substrate-holding portion has a first depth, and the second substrate-holding portion has a second depth which is larger than the first depth. The gas supply unit supplies precursors to the susceptor. The rotation unit is used to rotate the susceptor. The heating unit is used to heat the susceptor while the susceptor is rotated by the rotation unit, so that the heating unit can heat the susceptor uniformly.

To achieve the above objective, a vapor deposition apparatus according to the invention includes a susceptor, a gas supply unit, a heating unit and a rotation unit. The susceptor has a plurality of substrate-holding portions for holding substrates respectively, and there exists an empty space under a substrate after the substrate is held in one of the substrate-holding portions. The gas supply unit supplies precursors to the susceptor. The rotation unit rotates the susceptor. The heating unit is used to heat the susceptor while the susceptor is rotated by the rotation unit. Accordingly, the heating unit can heat the susceptor uniformly.

To achieve the above objective, a susceptor for semiconductor processing apparatus according to the invention includes a plurality of substrate-holding portions including a first substrate-holding portion and a second substrate-holding portion. The first substrate-holding portion has a first depth, and the second substrate-holding portion has a second depth which is larger than the first depth.

As mentioned above, because the second substrate-holding portion of the susceptor in the invention is deeper than the first substrate-holding portion, the substrate (such as a wafer) disposed in the second substrate-holding portion can not directly contact the susceptor with high temperature and thus the temperature thereof can be properly adjusted. Accordingly, the temperature of the substrate accommodated in the substrate-holding portion located at the central area of the susceptor can be lower than that of the corresponding substrate-holding portion, so that the properties of the manufactured chips can be kept in more uniformity. Besides, due to the configuration of the empty space, the substrate-holding portion of the invention can not directly contact the susceptor, so that the temperature of the substrate in the substrate-holding portion can be adjusted. Accordingly, the temperature of the substrate accommodated in the substrate-holding portion located at the central area of the susceptor can be lower than that of the corresponding substrate-holding portion, so that the properties of the manufactured chips can be kept in more unity.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic diagram of a conventional susceptor;

FIG. 2 is a schematic diagram of a conventional wafer-holding portion;

FIG. 3 is a schematic diagram of a vapor deposition apparatus of a preferred embodiment of the present invention;

FIGS. 4A and 4B are schematic diagrams of a first substrate-holding portion and a second substrate-holding portion of a preferred embodiment of the present invention respectively;

FIGS. 5A to 5C are schematic diagrams showing various aspects of the substrate-holding portion of a preferred embodiment of the present invention respectively;

FIG. 6 is a schematic diagram of another vapor deposition apparatus of a preferred embodiment of the preset invention; and

FIG. 7 is a top view of the susceptor shown in FIG. 6.

### DETAILED DESCRIPTION OF THE INVENTION

The present invention will be apparent from the following detailed description, which proceeds with reference to the accompanying drawings, wherein the same references relate to the same elements.

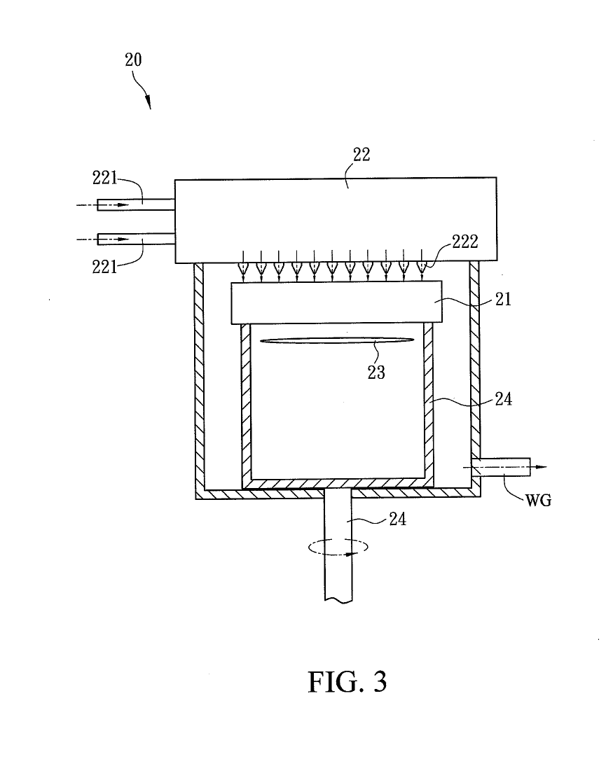

As shown in FIG. 3, a vapor deposition apparatus 20 according to a preferred embodiment of the invention includes a susceptor 21, a gas supply unit 22, a heating unit 23 and a rotation unit 24. The vapor deposition apparatus 20 according to the preferred embodiment, for example, is a chemical vapor deposition apparatus.

The susceptor 21 has a plurality of substrate-holding portions, each of which can accommodate a substrate, such as a wafer. The material of the substrate can include, for example, GaAs, GaP, InP, Si, SiC or Sapphire. The susceptor 21 can be made from graphite, or other materials resistant to reaction in the processing.

The gas supply unit 22 supplies precursors to the susceptor 21. In general for MOCVD processing, the precursors include metalorganic gas and hydride gas. The metalorganic gas includes TMGa (Trimethylgallium), TMAl (Trimethylaluminum), TMIn(Trimethylindium), Cp2Mg (Bis(cyclopentadienyl)mag-nesium), or DIPTe (Diisopropyltelluride), and the hydride gas includes AsH3, PH3, NH3, or Si2H6. The gas supply unit 22 has a plurality of inlets 221 for supplying the precursors such as metalorganic gas and hydride gas respectively, and a plurality of outlets 222 for dispersing the precursors into the reaction chamber. The vapor deposition apparatus 20 further has an exhaust outlet WG for dispersing the exhaust gas of the reaction.

The heating unit 23 is used to heat the susceptor 21, so that the susceptor 21 can effectively receive the heat from the heating unit 23 to achieve the temperature required for the growth of thin film. The heating unit 23 can be disposed under the susceptor 21 for example, and can use infrared lamp, hot wire, microwave or the likes as the heating source.

The heating unit 23 is used to heat the susceptor 21 while the susceptor 21 is rotated by the rotation unit 24, so that the heating unit 23 can heat the susceptor 21 uniformly and further improve the uniformity of the characteristics of the manufactured chips.

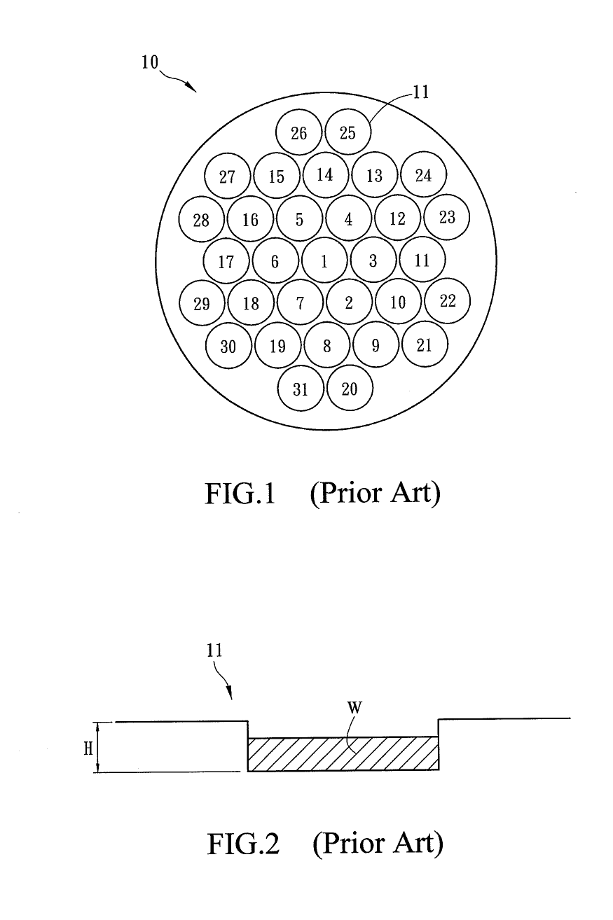

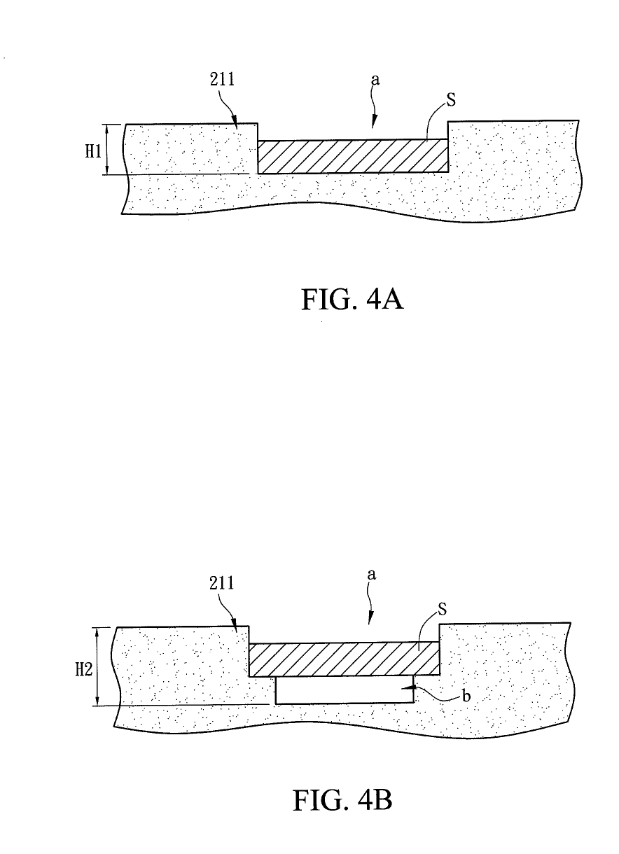

A top view of the susceptor 21 can be known by referring to FIG. 1. As shown in FIG. 1, the susceptor 21 has 31 substrate-holding portions 211 (No. 1 to No. 31). The substrate-holding portion is a depression for accommodating the substrate. The cross-sectional view of the substrate-holding portions 211 of No. 2 to No. 31 is shown in FIG. 4A, and these substrate-holding portions 211 have a first depth H1. The cross-sectional view of the substrate-holding portion 211 of No. 1 is shown in FIG. 4B, and this substrate-holding portion 211 has a second depth H2 which is larger than the first depth H1.

As shown in FIG. 4B, the substrate-holding portion 211 of No. 1 has a first depression a and a second depression b, and the width of the first depression a is larger than that of the second depression b, so that the substrate S can be disposed in the first depression a without falling into the second depression b. Accordingly, due to the configuration of the second depression b, the substrate S in the substrate-holding portion 211 of No. 1 located at the central area of the susceptor 21 does not directly contact the susceptor with higher temperature and thus can lower temperature of substrate inside the substrate-holding portion 211 of No. 1, so that the substrate inside the substrate-holding portion 211 of No. 1 has a temperature close to or substantially equal to that of the other substrates accommodated in the substrate-holding portions 211 of No. 2 to No. 31. Therefore, the uniformity of the characteristics of the manufactured chips can be kept equally. In other words, there exists an empty space under the substrate S after it is disposed in the substrate-holding portion 211 of No. 1. The empty space here is defined as the second depression b.

To be noted, the substrate-holding portions 211 of No. 2 to No. 31 can be regarded as the first substrate-holding portion as recited in the claims, and the substrate-holding portion of No. 1 can be regarded as the second substrate-holding portion as recited in the claims, but this is just for illustration as an example only and is not for limiting the scope of the invention. The number and the position of the first substrate-holding portion and the second substrate-holding portion will not be limited in the invention.

Besides, the dimensions of the second depression b (empty space) are not limited in the embodiment. For example, the depth of the second depression b can be larger or equal to 1 micrometer and less or equal to 500 micrometers. Furthermore, the empty space of the embodiment can be varied in many aspects, as described below for example.

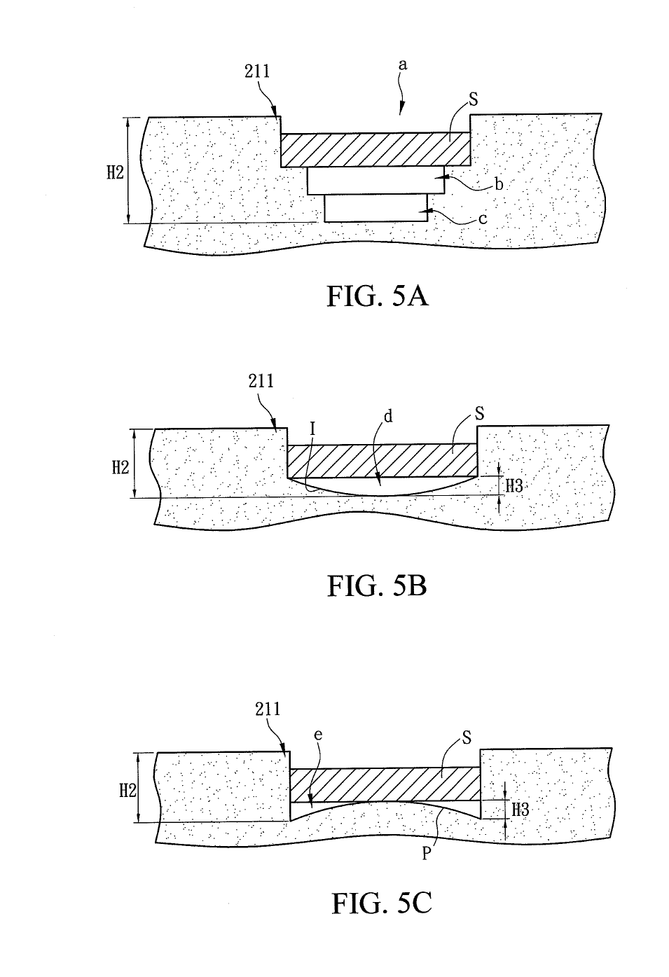

As shown in FIG. 5A, in addition to the second depression b, the substrate-holding portion 211 can further have a third depression c, and the width of the second depression b is larger than that of the third depression c. Besides, the width of the substrate S is larger than that of the second depression b and the third depression c, so that the substrate S can be kept in the first depression a. The depth of the third depression c can be, for example, larger than or equal to 1 micrometer and less than or equal to 500 micrometers. Similarly, due to the configuration of the second depression b and the third depression c, the temperature of the substrate S disposed in the substrate-holding portion 211 can be adjusted, and for example, can be substantially equal to the temperatures of the substrates disposed in other substrate-holding portions. Herein, the empty space includes the second depression b and the third depression c, and that is, the empty space is a multi-level depression.

As shown in FIG. 5B, there exists an empty space d under the substrate S after it is disposed in the substrate-holding portion 211. Due to the configuration of the empty space, the temperature of the substrate S disposed in the substrate-holding portion 211 can be adjusted, and for example, can be substantially equal to the temperatures of the substrates disposed in other substrate-holding portions. The depth H3 of the empty space d can be, for example, larger than or equal to 1 micrometer and less than or equal to 500 micrometers. Furthermore, in the embodiment, the substrate-holding portion 211 has a concave I in the empty space d. In other words, the concave I is disposed to a bottom of the substrate-holding portion 211.

As shown in FIG. 5C, the substrate-holding portion 211 has a convex P in the empty space e, and in other words, the convex P is disposed to a bottom of the substrate-holding portion 211.

The vapor deposition apparatus 20 as mentioned above is a vertical flow type vapor deposition apparatus in which the precursors are supplied to the substrate on the susceptor in a vertical direction. Besides, the invention also can be applied to the horizontal flow type vapor deposition apparatus, as described below.

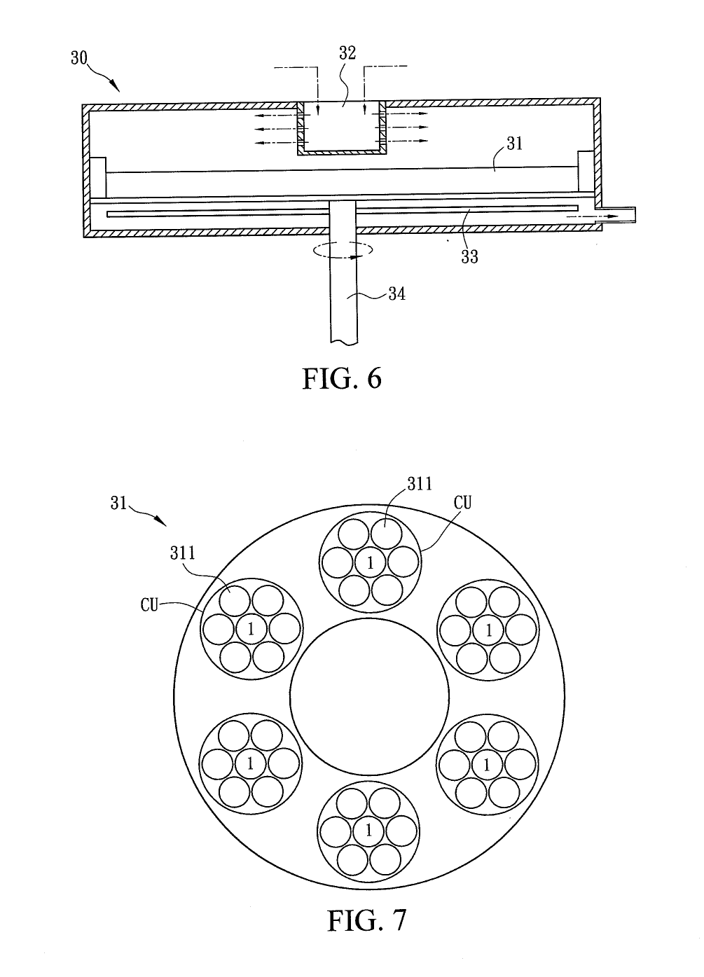

As shown in FIG. 6, a horizontal flow type vapor deposition apparatus 30 includes a susceptor 31, a gas supply unit 32, a heating unit 33 and a rotation unit 34. The technological features of the components of the vapor deposition apparatus 30 can be referred to those of the above-mentioned vapor deposition apparatus 20. The main difference between the vapor deposition apparatuses 30 and 20 is that the gas supply unit 32 of the vapor deposition apparatus 30 supplies the precursors in a horizontal direction. In addition, the susceptor 31 as shown in FIG. 7 has a plurality of carrying units CU, each of which has a plurality of substrate-holding portions 311 for accommodating the substrates. The carrying units CU can have a rotation function or be rotated by the rotation unit 34.

Similar to the substrate-holding portions 211, the substrate-holding portions 311 of the susceptor 31 can have different depths or empty spaces. Accordingly, the temperature of the substrate accommodated in the substrate-holding portion 311 can be adjusted. For example, the temperature of the substrate accommodated in the substrate-holding portion 311 of No. 1 can be lowered to be substantially equal to the temperature of the substrates accommodated in other substrate-holding portions, so as to keep the uniformity of the properties of the manufactured chips and thus enhance the production yield. The features of the substrate-holding portion having different depths or empty spaces are illustrated clearly in the above embodiments, so the detailed descriptions thereof are omitted.

To be noted, the susceptor disclosed by the invention can not only be applied to the vapor deposition apparatus but also be applied to the other semiconductor apparatus, such as ICP (inductively coupled plasma) etching apparatus.

In summary, because the second depth of the second substrate-holding portion of the susceptor in the invention is larger than the first depth of the first substrate-holding portion, the substrate (such as a wafer) disposed in the second substrate-holding portion will not directly contact the susceptor with high temperature due to the configuration of the empty space and thus the temperature thereof can be properly adjusted. Accordingly, the temperature of the substrate accommodated in the substrate-holding portion located at the central area of the susceptor can be lowered, so that the properties of the manufactured chips can be more uniform. In other words, due to the configuration of the empty space, the substrate-holding portion of the invention will not directly contact the susceptor, so that the temperature of the substrate in the substrate-holding portion can be adjusted. Accordingly, the temperature of the substrate accommodated in the substrate-holding portion located at the central area of the susceptor can be lowered, so that the properties of the manufactured chips can be more uniform.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A vapor deposition apparatus, comprising:
a susceptor having a first substrate-holding portion and a second substrate-holding portion, wherein the first substrate-holding portion has a first depth, the second substrate-holding portion has a second depth which is larger than the first depth;
a gas supply unit supplying precursors to the susceptor;
a rotation unit used to rotate the susceptor; and
a heating unit heating the susceptor while the susceptor is rotated by the rotation unit.

2. The vapor deposition apparatus as recited in claim 1, wherein the second substrate-holding portion is located at the central area of the susceptor.

3. The vapor deposition apparatus as recited in claim 1, wherein the second substrate-holding portion has a first depression and a second depression, and the width of the first depression is larger than that of the second depression.

4. The vapor deposition apparatus as recited in claim 3, wherein the depth of the second depression is larger than or equal to 1 micrometer and less than or equal to 500 micrometers.

5. The vapor deposition apparatus as recited in claim 3, wherein the second substrate-holding portion further has a third depression, and the width of the second depression is larger than that of the third depression.

6. The vapor deposition apparatus as recited in claim 1, wherein a convex or a concave is configured at a bottom of the second substrate-holding portion.

7. The vapor deposition apparatus as recited in claim 1, wherein said vapor deposition apparatus is a vertical-flow type metal-organic chemical vapor deposition (MOCVD) apparatus, the gas supply unit supplying precursors in a vertical direction to the susceptor.

8. The vapor deposition apparatus as recited in claim 1, wherein said vapor deposition apparatus is a horizontal-flow type metal-organic chemical vapor deposition (MOCVD) apparatus, the gas supply unit supplying precursors in a horizontal direction to the susceptor.

9. A vapor deposition apparatus, comprising:
a susceptor having a plurality of substrate-holding portions for holding substrates respectively, wherein there exists an empty space under the substrate after the substrate is held in one of the substrate-holding portions;
a gas supply unit supplying precursors to the susceptor;
a rotation unit rotating the susceptor; and
a heating unit heating the susceptor while said susceptor is rotated by the rotation unit.

10. The vapor deposition apparatus as recited in claim 9, wherein the substrate-holding portion having the empty space is located at the central area of the susceptor.

11. The vapor deposition apparatus as recited in claim 9, wherein the empty space is a multi-level depression.

12. The vapor deposition apparatus as recited in claim 9, wherein the depth of the empty space is larger than or equal to 1 micrometer and less than or equal to 500 micrometers.

13. The vapor deposition apparatus as recited in claim 9, wherein the substrate-holding portion has a convex or a concave located in the empty space.

14. The vapor deposition apparatus as recited in claim 9, wherein said vapor deposition apparatus is a vertical-flow type metal-organic chemical vapor deposition (MOCVD) apparatus, the gas supply unit supplying precursors in a vertical direction to the susceptor.

15. The vapor deposition apparatus as recited in claim 9, wherein said vapor deposition apparatus is a horizontal-flow type metal-organic chemical vapor deposition (MOCVD) apparatus, the gas supply unit supplying precursors in a horizontal direction to the susceptor.

16. A susceptor for semiconductor processing apparatus, comprising:
a plurality of substrate-holding portions including a first substrate-holding portion and a second substrate-holding portion, wherein the first substrate-holding portion has a first depth, the second substrate-holding portion has a second depth which is larger than the first depth.

17. The susceptor as recited in claim 16, wherein the second substrate-holding portion is located at the central area of the susceptor.

18. The susceptor as recited in claim 16, wherein the second substrate-holding portion has a first depression and a second depression, and the width of the first depression is larger than that of the second depression.

19. A susceptor for semiconductor processing apparatus, comprising:
a plurality of substrate-holding portions for holding substrates respectively, wherein there exists an empty space under the substrate after the substrate is held in one of the substrate-holding portions.

20. The susceptor as recited in claim 19, wherein the substrate-holding portion having the empty space is located at the central area of the susceptor.
